(19) United States
(12) Patent Application Publication
(10) Pub. No.: US 2023/0060329 A1
(43) Pub. Date: Mar. 2, 2023

(54) PLASMA PROCESSING APPARATUS AND ABNORMAL DISCHARGE CONTROL METHOD

(71) Applicant: Tokyo Electron Limited, Tokyo (JP)

(72) Inventor: Takehiro TANIKAWA, Miyagi (JP)

(73) Assignee: Tokyo Electron Limited, Tokyo (JP)

(21) Appl. No.: 17/899,087

(22) Filed: Aug. 30, 2022

Related U.S. Application Data
(60) Provisional application No. 63/260,700, filed on Aug. 30, 2021.

(30) Foreign Application Priority Data
Feb. 1, 2022 (JP) 2022-013878
Aug. 22, 2022 (JP) 2022-131484

(51) Int. Cl. H01J 37/32

(52) U.S. Cl. CPC H01J 37/32449; H01J 37/32715; H01J 37/32642; H01J 37/32211

(57) ABSTRACT

There is provided a plasma processing apparatus comprising: a chamber; a mounting stage mounting a substrate and a ring assembly on a periphery of the substrate; a fixation portion fixing at least one of the substrate and the ring assembly to the mounting stage; a heat transfer gas supply supplying heat transfer gas between the mounting stage and at least one of the substrate and the ring assembly; a heat transfer gas exhauster exhausting the heat transfer gas therefrom; an RF power supply supplying an RF signal for plasma generation; and a controller controlling the heat transfer gas supply so that pressure of the heat transfer gas is lower than that at the time of plasma processing for the substrate before performing the plasma processing for the substrate when at least one of the substrate and the ring assembly is mounted on the mounting stage.

### CROSS-REFERENCE TO RELATED APPLICATIONS

This application claims priority to U.S. Provisional Patent Application No. 63/260,700 filed on Aug. 30, 2021, Japanese Patent Application No. 2022-013878 filed on Feb. 1, 2022, and Japanese Patent Application No. 2022-131484 filed on Aug. 22, 2022, respectively, the entire contents of which are incorporated herein by reference and priority is claimed to each.

### TECHNICAL FIELD

The present disclosure relates to a plasma processing apparatus and an abnormal discharge control method.

### BACKGROUND

US Patent Publication No. 2008/0236751 discloses a configuration for supplying gas such as He, Ar, Xe, etc. from a gas supply insulation boss on a back side of a focus ring. Further, US Patent Publication No. 2008/0236751 discloses that the gas supply insulation boss is a portion which is easily abnormally discharged due to relatively high gas pressure.

### SUMMARY

The present disclosure provides a technique that controls occurrence of abnormal discharge.

In accordance with one aspect of the present disclosures, there is provided a plasma processing apparatus comprising: a chamber, a mounting stage, a fixation portion, a heat transfer gas supply, a heat transfer gas exhauster, an RF power supply, and a controller. In the chamber, plasma processing is performed. The mounting stage, disposed in the chamber, mounts a substrate and a ring assembly on a periphery of the substrate. The fixation portion, provided in the mounting stage, fixes at least one of the substrate and the ring assembly to the mounting stage. The heat transfer gas supply supplies heat transfer gas between the mounting stage and at least one of the substrate and the ring assembly. The heat transfer gas exhauster exhausts the heat transfer gas from between the mounting stage and at least one of the substrate and the ring assembly. The RF power supply supplies a radio frequency (RF) signal for plasma generation into the chamber. The controller controls the heat transfer gas supply so that pressure of the heat transfer gas supplied from the heat transfer gas supply is lower than that at the time of plasma processing for the substrate before performing the plasma processing for the substrate when at least one of the substrate and the ring assembly is mounted on the mounting stage.

### BRIEF DESCRIPTION OF THE DRAWINGS

FIG. 1 is a block diagram illustrating an example of a schematic configuration of a plasma processing system according to an exemplary embodiment.

FIG. 2 is a diagram for describing an example of occurrence of abnormal discharge according to an exemplary embodiment.

FIG. 3 is a diagram schematically illustrating an example of a state at the time of seasoning according to a comparative example.

FIG. 4 is a diagram schematically illustrating an example of a state at the time of seasoning according to an exemplary embodiment.

FIG. 5 is a diagram for describing an example of a flow of removing impurities according to an exemplary embodiment.

FIG. 6 is a diagram for describing an example of a processing sequence of an abnormal discharge control method according to an exemplary embodiment.

FIG. 7 is a diagram for describing another example of a flow of removing impurities according to an exemplary embodiment.

FIG. 8 is a diagram for describing another example of a processing sequence of an abnormal discharge control method according to an exemplary embodiment.

### DETAILED DESCRIPTION

Hereinafter, exemplary embodiments of a plasma processing apparatus and an abnormal discharge control method disclosed by the present disclosure will be described in detail with reference to the accompanying drawings. Further, the plasma processing apparatus and the abnormal discharge control method are not limited to the exemplary embodiment.

A plasma processing apparatus is known, which depressurizes the inside of a chamber and performs plasma processing such as plasma etching on a substrate. The plasma processing apparatus has a mounting stage provided in the chamber. A substrate is disposed and a ring assembly such as a focus ring is mounted to surround the substrate, on the mounting stage. Heat transfer gas such as helium is supplied between the substrate or the ring assembly and the mounting stage for heat transfer.

However, in the plasma processing apparatus, there is a case where abnormal discharge such as arcing occurs between the substrate or the ring assembly and the mounting stage. Therefore, a technique for controlling the occurrence of the abnormal discharge is expected.

### Exemplary Embodiment

[Apparatus Configuration]

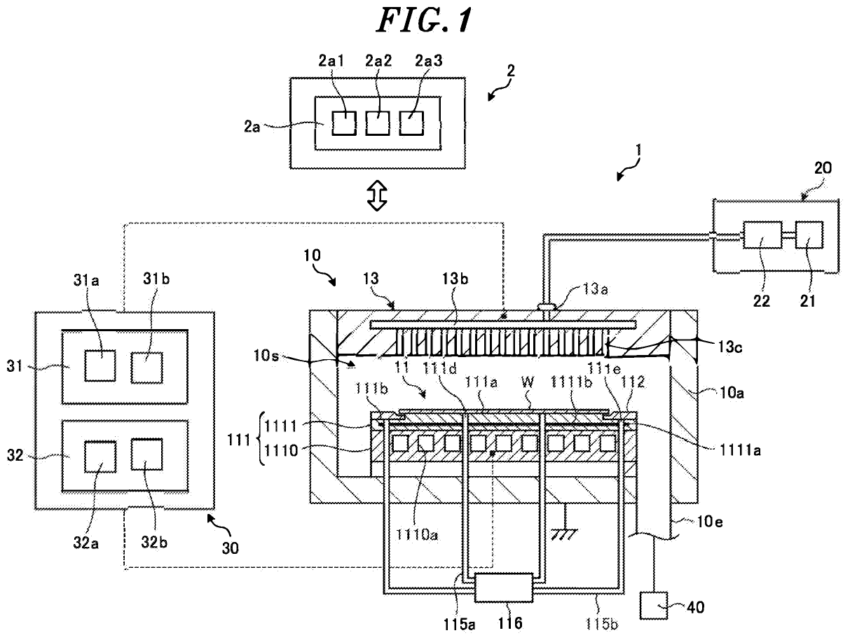

An example of the plasma processing apparatus of the present disclosure will be described. In the exemplary embodiment to be described below, a case where the plasma processing apparatus of the present disclosure is configured by a plasma processing system having a system configuration will be described as an example. FIG. 1 is a block diagram illustrating an example of a schematic configuration of a plasma processing system according to an exemplary embodiment.

Hereinafter, a configuration example of a plasma processing system will be described. FIG. 1 is a diagram for describing a configuration example of a capacitively coupled plasma processing apparatus.

The plasma processing system includes a capacitively coupled plasma processing apparatus 1 and a controller 2. The capacitively coupled plasma processing apparatus 1 includes a plasma processing chamber 10, a gas supply 20, a power supply 30, and an exhaust system 40. Further, the plasma processing apparatus 1 includes a substrate support 11 and a gas introducer. The gas introducer is configured to introduce at least one processing gas into the plasma processing chamber 10. The gas introducer includes a shower head 13. The substrate support 11 is disposed in the plasma processing chamber 10. The shower head 13 is disposed above the substrate support 11. In an exemplary embodiment, the shower head 13 constitutes at least a part of a ceiling of the plasma processing chamber 10. The plasma processing chamber 10 includes the shower head 13, a side wall 10a of the plasma processing chamber 10, and a plasma processing space 10s defined by the substrate support 11. Further, the plasma processing chamber 10 includes at least one gas supply port for supplying at least one processing gas to the plasma processing space 10s and at least one discharge port for discharging gas from the plasma processing space. The plasma processing chamber 10 is grounded. The shower head 13 and the substrate support 11 are electrically insulated from a housing of the plasma processing chamber 10.

The substrate support 11 includes a body portion 111 and a ring assembly 112. The body portion 111 has a central area 111a for supporting the substrate W and a ring-shaped area 111b for supporting the ring assembly 112. A wafer is an example of the substrate W. The ring-shaped area 111b of the body portion 111 surrounds the central area 111a of the body portion 111 in a plan view. The substrate W is disposed on the central area 111a of the body portion 111, and the ring assembly 112 is disposed on the ring-shaped area 111b of the body portion 111 to surround the substrate W on the central area 111a of the body portion 111. Therefore, the central area 111a is also referred to as a substrate support surface for supporting the substrate W, and the ring-shaped area 111b is also referred to as a ring support surface for supporting the ring assembly 112.

The substrate support 11 has a fixation portion. The fixation portion fixes at least one of the substrate W and the ring assembly 112. In the exemplary embodiment, the fixation portion fixes at least one of the substrate W and the ring assembly 112 to the substrate support 11 by electrostatic adsorption. In an exemplary embodiment, the body portion 111 includes a base 1110 and an electrostatic chuck 1111. The base 1110 includes a conductive member. The conductive member of the base 1110 may serve as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central area 111a. In an exemplary embodiment, the ceramic member 1111a has also the ring-shaped area 111b. In the exemplary embodiment, the electrostatic chuck 1111 corresponds to the fixation portion of the present disclosure. When the substrate W and the ring assembly 112 are electrostatically adsorbed, voltage from a DC power supply is applied to the electrostatic chuck 1111. The electrostatic chuck 111 fixes the substrate W and the ring assembly 112 by the electrostatic adsorption. Further, another member surrounding the electrostatic chuck 1111, such as a ring-shaped electrostatic chuck or a ring-shaped insulating member may have the ring-shaped area 111b. In this case, the ring assembly 112 may be disposed on the ring-shaped electrostatic chuck or the ring-shaped insulating member or disposed on both the electrostatic chuck 1111 and the ring-shaped insulating member. Further, at least one RF/DC electrode coupled to a radio frequency (RF) power supply 31 and/or direct current (DC) power supply 32 to be described below may be disposed in the ceramic member 1111a. In this case, at least one RF/DC electrode serves as the lower electrode. When a bias RF signal and/or DC signal to be described below is supplied to at least one RF/DC electrode, the RF/DC electrode is also called a bias electrode. Further, the conductive member of the base 1110 and at least one RF/DC electrode may serve as a plurality of lower electrodes. Further, the electrostatic electrode 1111b may serve as the lower electrode. Therefore, the substrate support 111 includes at least one lower electrode.

The ring assembly 112 includes one or a plurality of ring-shaped members. In an exemplary embodiment, one or the plurality of ring-shaped members includes one or a plurality of edge rings and at least one cover ring. The edge ring is made of a conductive material or an insulating material, and the cover ring is made of an insulating material.

Further, the substrate support 11 may include a temperature control module configured to control at least one of the electrostatic chuck 1111, the ring assembly 112, and the substrate at a target temperature. The temperature control module may include a heater, a heat transfer medium, a path 1110a, or a combination thereof. In the path 1110a, a heat transfer fluid such as brine or gas flows. In an exemplary embodiment, the path 1110a is formed in the base 1110 and one or a plurality of heaters is/are disposed in the ceramic member 1111a of the electrostatic chuck 1111. Further, the substrate support 11 may include a heat transfer gas supply configured to supply heat transfer gas to a gap between a back surface of the substrate W and the central area 111a. Further, the substrate support 11 may be configured to supply the heat transfer gas to the gap between the back surface of the ring assembly 112 and the ring-shaped area 111b.

For example, a gas supply port 111d discharging the heat transfer gas is formed at the central area 111a of the substrate support 11. Further, a gas support port 111e discharging the heat transfer gas is formed at the ring-shaped area 111b of the substrate support 11. Supply paths 115a and 115b such as a pipe supplying the heat transfer gas are provided in the substrate support 11. The supply path 115 is in communication with the gas supply port 111d. The supply path 115b is in communication with the gas supply port 111e. The supply paths 1115a and 115b are connected to the gas supply 116. The gas supply 116 is configured to individually control a flow rate of the heat transfer gas such as helium gas (He) gas or hydrogen (H₂) gas and supply the heat transfer gas to the supply paths 115a and 115b. Further, the gas supply 116 is configured to exhaust the heat transfer gas from the supply paths 115a and 115b. The heat transfer gas supplied through the supply path 115a is discharged from the gas supply port 111d and supplied to a space between the substrate W and the central area 111a. The heat transfer gas supplied through the supply path 115b is discharged from the gas supply port 111e and supplied to a space between the ring assembly 112 and the ring-shaped area 111b. Further, the heat transfer gas supplied to the space between the substrate W and the central area 111a is exhausted through the supply path 115a. The heat transfer gas supplied to the space between the ring assembly 112 and the ring-shaped area 111b is exhausted through the supply path 115b. The gas supply 116 corresponds to a heat transfer gas supply and a heat transfer gas exhauster of the present disclosure. Further, the gas supply 116 may be configured to be divided into a portion supplying the heat transfer gas and a portion exhausting the heat transfer gas.

The shower head 13 is configured to introduce at least one processing gas from the gas supply 20 into the plasma processing space 10s. The shower head 13 includes at least one gas supply port 13a, at least one gas diffusion chamber 13b, and a plurality of gas introduction ports 13c. The processing gas supplied to the gas supply port 13a is introduced into the plasma processing space 10s from the plurality of gas introduction ports 13c by passing through the gas diffusion chamber 13b. Further, the shower head 13 includes at least one upper electrode. Further, the gas introducer may include one or a plurality of side gas injectors (SGI) mounted on one or a plurality of openings formed on the side wall 10a in addition to the shower head 13.

The gas supply 20 may include at least one gas source 21 and at least one flow rate controllers 22. In an exemplary embodiment, the gas supply 20 is configured to supply at least one processing gas to the shower head 13 from the gas source 21 corresponding to the gas supply 20 through the flow rate controller 22 corresponding thereto, respectively. Each flow rate controller 22 may include, for example, a mass-flow controller or a pressure control type flow rate controller. Further, the gas supply 20 may include one or more flow rate modulation devices which modulate or pulse the flow rate of at least one processing gas.

The power supply 30 includes an RF power supply 31 coupled to the plasma processing chamber 10 through at least one impedance matching circuit. The RF power supply 31 is configured to supply at least one RF signal (RF power) to at least one lower electrode and/or at least one upper electrode. As such, plasma is formed from at least one processing gas supplied to the plasma processing space 10s. Therefore, the RF power supply 31 may serve as at least a part of a plasma generator configured to generate plasma from one or more processing gas in the plasma processing chamber 10. Further, by supplying the bias RF signal to at least one lower electrode, a bias potential may be generated on the substrate W and ion components in the formed plasma may be drawn to the substrate W.

In an exemplary embodiment, the RF power supply 31 includes a first RF generator 31a and a second RF generator 31b. The first RF generator 31a is configured to be coupled to at least one lower electrode and/or at least one upper electrode through at least one impedance matching circuit, and to generate a source RF signal (source RF power) for plasma generation. In an exemplary embodiment, the source RF signal has a frequency in a range of 10 to 150 MHz. In an exemplary embodiment, the first RF generator 31a may be configured to generate a plurality of source RF signals having different frequencies. One or a plurality of source RF signals generated is supplied to at least one lower electrode and/or at least one upper electrode.

The second RF generator 31b is configured to be coupled to at least one lower electrode through at least one impedance matching circuit, and to generate the bias RF signal (bias RF power). A frequency of the bias RF signal may be the same as or different from the frequency of the source RF signal. In an exemplary embodiment, the bias RF signal has a lower frequency than the source RF signal. In an exemplary embodiment, the bias RF signal has a frequency in a range of 100 kHz to 60 MHz. In an exemplary embodiment, the second RF generator 31b may be configured to generate a plurality of bias RF signals having different frequencies. One or a plurality of bias RF signals generated is supplied to at least one lower electrode. Further, in various exemplary embodiments, at least one of the source RF signal and the bias RF signal may be pulsed.

Further, the power supply 30 may include the DC power supply 32 coupled to the plasma processing chamber 10. The DC power supply 32 includes a first DC generator 32a and a second DC generator 32b. In an exemplary embodiment, the first DC generator 32a is configured to be connected to at least one lower electrode and generate a first DC signal. The generated first DC signal is applied to at least one lower electrode. In an exemplary embodiment, the second DC generator 32b is configured to be connected to at least one upper electrode and generate a second DC signal. The generated second DC signal is applied to at least one upper electrode.

In various exemplary embodiments, at least one of first and second DC signals may be pulsed. In this case, a sequence of a voltage pulse is applied to at least one lower electrode and/or at least one upper electrode. The voltage pulse may have a pulse waveform of a rectangle, a trapezoid, a triangle, or a combination thereof. In an exemplary embodiment, a waveform generator for generating the sequence of the voltage sequence from the DC signal is connected between the first DC generator 32a and at least one lower electrode. Therefore, the first DC generator 32a and the waveform generator constitute a voltage pulse generation portion. When the second DC generator 32b and the waveform generator constitute the voltage pulse generation portion, the voltage pulse generator is connected to at least one upper electrode. The voltage pulse may have a positive polarity or a negative polarity. Further, the sequence of the voltage pulse may include one or multiple voltage positive voltage pulses and one or multiple negative voltage pulses within one cycle. Further, the first and second DC generation portions 32a and 32b may be provided in addition to the RF power supply 31 or the first DC generator 32a may be provided instead of the second RF generator 31b.

The exhaust system 40 may be connected to a gas outlet 10e provided on a bottom of the plasma processing chamber 10, for example. The exhaust system 40 may include a pressure adjustment valve and a vacuum pump. By the pressure adjustment valve, pressure in the plasma processing space 10s is adjusted. The vacuum pump may include a turbo molecule pump, a dry pump, or a combination thereof.

The controller 2 processes a computer executable command which allows the plasma processing apparatus 1 to execute various processes described in the present disclosure. The controller 2 may be configured to control each element of the plasma processing apparatus 1 so as to execute various processes described herein. In an exemplary embodiment, a part or the entirety of the controller 2 may be included in the plasma processing apparatus 1. The controller 2 may include a processor 2a1, a storage 2a2, and a communication interface 2a3. The controller 2 is realized by a computer 2a, for example. The processor 2a1 may be configured to perform various control operations by reading a program from the storage 2a2 and executing the read program. The program may be stored in the storage 2a2 in advance or obtained through a medium as necessary. The obtained program is stored in the storage 2a2, and read and executed from the storage 2a2 by the processor 2a1. The medium may be various storage media readable by the computer 2a or a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 through a communication line such as local area network (LAN), etc.

Next, a flow of performing plasma processing such as plasma etching for the substrate W by the plasma processing system according to the exemplary embodiment will be described in brief. The substrate W is mounted on the substrate support 11 by a transport mechanism such as a transport arm which is not illustrated. The plasma processing apparatus 1 depressurizes the inside of the plasma processing chamber 10 by the exhaust system 40 when executing the plasma processing for the substrate W. The electrostatic chuck 111 fixes the substrate W and the ring assembly 112 by the electrostatic adsorption. The controller 2 controls high-frequency power for adsorption from the power supply 30 to be applied to the substrate support 11 when the electrostatic chuck 1111 performs electrostatic adsorption. For example, the controller 2 controls the power supply 30, and as a result, the electrostatic chuck 1111 applies the high-frequency power which enables the substrate W and the ring assembly 112 to be electrostatically adsorbed to the substrate support 11. The plasma processing apparatus 1 supplies the processing gas from the gas supply unit 20 to introduce the processing gas in the plasma processing chamber 10 from the shower head 13. In addition, the plasma processing apparatus 1 supplies at least one RF signal from the RF power supply 31 to generate the plasma in the plasma processing space 10s and performs the plasma processing for the substrate W.

However, there is a case where a defect occurs between the substrate W or the ring assembly 112 and the substrate support 11 in the plasma processing apparatus 1. For example, there is a case where abnormal discharge such as arcing occurs between the substrate W or the ring assembly 112 and the substrate support 11.

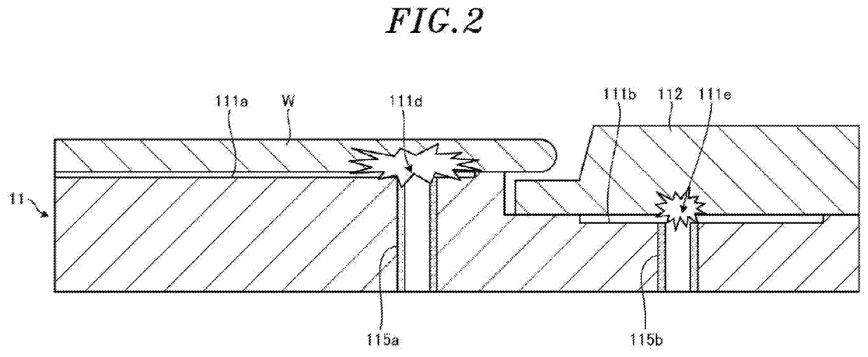

FIG. 2 is a diagram for describing an example of occurrence of abnormal discharge according to an embodiment. In FIG. 2, a vicinity of the substrate support 11 of the plasma processing chamber 10 is enlarged and schematically illustrated. In the substrate support 11, the substrate W is mounted at the central area 111a, and the ring assembly 112 is mounted on the ring-shaped area 111b to surround the substrate W. The gas supply port 111d is formed at the central area 111a of the substrate support 11. The gas support port 111e is formed at the ring-shaped area 111b of the substrate support 11. The gas supply 111d is in communication with the supply path 115a and the heat transfer gas is supplied from the gas supply 116 through the supply path 115a. The gas supply 111e is in communication with the supply path 115b and the heat transfer gas is supplied from the gas supply 116 through the supply path 115b. The gas supply 111d and the gas supply 111e discharge the heat transfer gas supplied from the gas supply 116.

In the substrate support surface 111a, a ring-shaped band is provided along an outer peripheral side of the substrate W and an outer periphery of the substrate W is supported by the band. Further, a dot (not illustrated) supporting the substrate W is formed in the substrate support surface 111a. A space in which the heat transfer gas is enabled to be flow is formed between the substrate W and the central area 111a.

In the ring-shaped area 111b, a ring-shaped band is provided along each of an inner peripheral side and an outer peripheral side of the ring assembly 112, and the inner periphery and the outer periphery of the ring assembly 112 are supported by the band. Further, a dot (not illustrated) supporting the ring assembly 112 is formed in the ring-shaped area 111b. The space in which the heat transfer gas is enabled to be flow is formed between the ring assembly 112 and the ring-shaped area 111b.

In the plasma processing apparatus 1, the ring assembly 112 is gradually consumed by the plasma processing. When the ring assembly 112 is consumed, the ring assembly 112 is exchanged. Moisture is attached to the exchanged ring assembly 112. In the plasma processing apparatus 1, when the ring assembly 1 is exchanged, seasoning (initializing process) in which generation of plasma is repeated is performed in order to stabilize a state in the plasma processing chamber 10, such as removal of moisture. For example, the plasma processing apparatus 1 depressurizes the inside of the plasma processing chamber 10 by the exhaust system 40 when executing the seasoning similarly to the case of the plasma processing. The electrostatic chuck 111 fixes the substrate W and the ring assembly 112 by the electrostatic adsorption. The plasma processing apparatus 1 applies the high-frequency power for adsorption from the power supply 30 to the substrate support 11 when the electrostatic chuck 1111 performs electrostatic adsorption. The plasma processing apparatus 1 supplies the processing gas from the gas supply unit 20 to introduce the processing gas in the plasma processing chamber 10 from the shower head 13. The processing gas may be the same as the plasma processing or a specific type of gas for seasoning. In addition, the plasma processing apparatus 1 supplies at least one RF signal from the RF power supply 31 to generate plasma in the plasma processing space 10s and perform the seasoning. In the seasoning, plasma is repeatedly generated until the inside of the plasma processing chamber 10 is stabilized. The seasoning is performed before performing the plasma processing of a manufacturing process of manufacturing a semiconductor device in the substrate W. The seasoning may be also performed by arranging the substrate W such as a dummy wafer in the substrate support 11.

However, there is a case where abnormal discharge such as arcing occurs between the ring assembly 112 and the substrate support 11 due to remaining moisture at the time of the seasoning. For example, when the ring assembly 112 is exchanged, there is a case where the abnormal discharge such as arcing occurs in the vicinity of the gas supply 111e or in the supply path 115b.

Further, there is a case where the defect occurs due to impurities attached to a back surface of the substrate W or the ring assembly 112. For example, when the substrate W or the ring assembly 112 is exchanged, there is a case where the abnormal discharge such as arcing occurs in the vicinity of the gas supply 111d or in the vicinity of the gas supply 111e or in the supply path 115a or the supply path 115b.

Therefore, in the exemplary embodiment, when the controller 2 exchanges at least one of the substrate W and the ring assembly 112, the controller 2 controls the pressure of the heat transfer gas supplied from the gas supply 116 to be lower than that at the time of plasma processing for the substrate W before performing the plasma processing for the substrate W.

For example, when the controller 2 exchanges the ring assembly 112, the controller 2 controls the pressure of the heat transfer gas supplied between the substrate support 11 and the ring assembly 112 to be lower than that at the time of the plasma processing for the substrate W, and controls the power of the RF signal supplied from the power supply 30 to be equal to or lower than that at the time of the plasma processing for the substrate W.

Further, when exchanging the substrate W or the ring assembly 112, the controller 2 controls the gas supply 116 to perform supply and exhaust of the heat transfer gas between the exchanged substrate W or ring assembly 112 and the substrate support 11 at least one time before performing the plasma processing for the substrate W.

An amount of moisture removed from the surface of the silicon increases at 200° C. or more and rises between 300° C. and 400° C. Therefore, at the time of the seasoning, it is preferable to set the temperature of the ring assembly 112 at 200° C. or more and more preferable to set the temperature of the ring assembly 112 at 300° C. or more. For example, at the time of the seasoning, it is more preferable to set the temperature of the ring assembly 112 between 300° C. and 400° C.

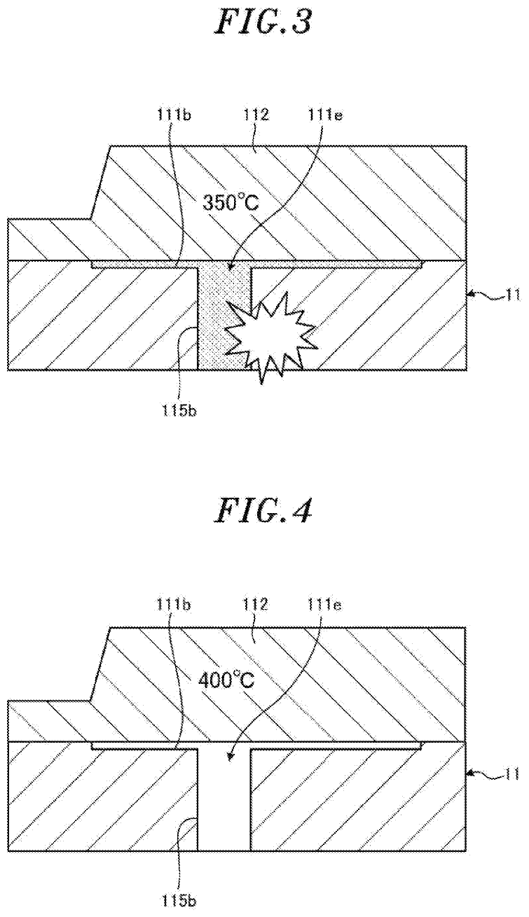

Here, as a comparative example, it is assumed that the plasma processing apparatus 1 performs the seasoning by setting the pressure of the heat transfer gas supplied from the gas supply 116 and the power of the RF signal supplied from the power supply 30 at the time of the seasoning similarly to the case of the plasma processing for the substrate W. In this case, since the temperature of the ring assembly 112 may be sufficiently raised by input heat from the plasma, it is possible to remove the moisture attached to the ring assembly 112. FIG. 3 is a diagram schematically illustrating an example of a state at the time of seasoning according to a comparative example. In FIG. 3, a state in the vicinity of the ring-shaped area 111b of the substrate support 11 is schematically illustrated. FIG. 3 illustrates a case of setting the pressure of the heat transfer gas supplied from the gas supply 116 and the power of the RF signal supplied from the power supply 30 at the time of the seasoning similarly to the case of the plasma processing for the substrate W. In FIG. 3, the temperature of the ring assembly 112 is set to 350° C. Therefore, the moisture is rapidly discharged from the ring assembly 112. However, there is a case where the abnormal discharge such as arcing occurs in the vicinity of the gas supply 111e or in the supply path 115b due to the moisture discharged from the ring assembly 112. Therefore, it is contemplated that the occurrence of the abnormal discharge is controlled by setting the power of the RF signal supplied from the power supply 30 at the time of the seasoning to be lower than that for the case of the plasma processing for the substrate W. However, when the power of the RF signal is lowered, the input heat into the ring assembly 112 from the plasma is lowered, and as a result, the temperature of the ring assembly 112 is not sufficiently raised. Therefore, the occurrence of the abnormal discharge may be controlled, but a time required for removing the moisture becomes longer, so the seasoning time becomes longer.

Therefore, in the exemplary embodiment, when the controller 2 exchanges the ring assembly 112, the controller 2 controls the pressure of the heat transfer gas supplied between the substrate support 11 and the ring assembly 112 to be lower than that at the time of the plasma processing for the substrate W, and controls the power of the RF signal supplied from the power supply 30 to be equal to or lower than that at the time of the plasma processing for the substrate W.

For example, the controller 2 controls the pressure of the heat transfer gas supplied between the substrate support 11 and the ring assembly 112 from the gas supply 116 at 15 Torr or less at the time of the seasoning. For example, the controller 2 controls the supply of the heat transfer gas from the gas supply 116 to a stopped state or minimizes the supply of the heat transfer gas in a lowest state by tightening the supply of the heat transfer gas maximally. Therefore, even when heat transfer to the ring-shaped area 111b of the substrate support 11 from the substrate W is reduced and the power of the RF signal is thus lowered, the temperature of the ring assembly 112 may be sufficiently raised.

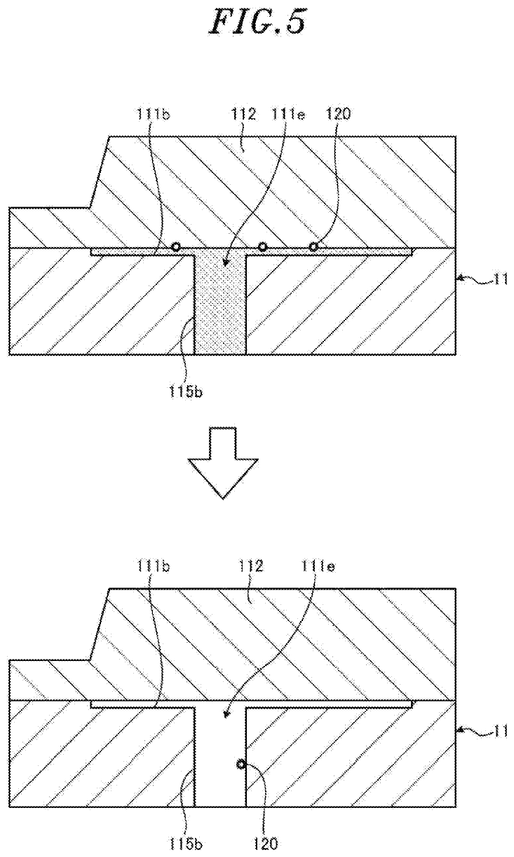

As described above, an amount of the moisture removed from the surface of the silicon increases at 200° C. or more. The controller 2 controls the power supply 30 so that an RF signal having a power which causes a temperature of the substrate to be 200° C. or more and is equal to or less than that at the time of the plasma processing for the substrate is to be supplied from the power supply 30 at the time of the seasoning. For example, even when the pressure of the heat transfer gas is lowered, the power of the RF signal in which the temperature of the substrate W becomes 200° C. or more is obtained by an experiment or a simulation in advance. As an example, the power of the RF signal in which the temperature of the substrate W becomes 300 to 400° C. is obtained. The controller 2 controls the high-frequency power of the power obtained in advance to be supplied from the power supply 30. FIG. 4 is a diagram schematically illustrating an example of a state at the time of seasoning according to an embodiment. In FIG. 4, a state in the vicinity of the ring-shaped area 111b of the substrate support 11 is schematically illustrated. FIG. 4 illustrates a case of setting the pressure of the heat transfer gas supplied from the gas supply 116 to be lower than that at the time of the plasma processing for the substrate W and setting the power of the RF signal supplied from the power supply 30 to be lower than that at the time of the plasma processing for the substrate W. In FIG. 4, the temperature of the ring assembly 112 is set to 400° C. Therefore, the moisture attached to the ring assembly 112 may be removed in a short time. Further, by lowering the pressure of the heat transfer gas, it is possible to control the occurrence of the abnormal discharge such as arcing in the vicinity of the gas supply 111e or in the supply path 115b.

Further, as described above, there is a case where the defect occurs due to the impurities attached to the back surface of the substrate W or the ring assembly 112. For example, when the substrate W or the ring assembly 112 is exchanged, there is a case where the abnormal discharge such as arcing occurs in the vicinity of the gas supply 111d or in the vicinity of the gas supply 111e or in the supply path 115a or the supply path 115b.

Therefore, in the exemplary embodiment, when exchanging the substrate W or the ring assembly 112, the controller 2 controls the gas supply 116 to perform supply and exhaust of the heat transfer gas between the exchanged substrate W or ring assembly 112 and the substrate support 11 at least one time before performing the plasma processing for the substrate W. For example, the controller 2 controls the gas supply 116 to alternately perform the supply and exhaust of the heat transfer gas multiple times. FIG. 5 is a diagram for describing an example of a flow of removing impurities according to an embodiment. In FIG. 5, a state in the vicinity of the ring-shaped area 111b of the substrate support 11 is schematically illustrated. An upper side of FIG. 5 indicates a state in which the heat transfer gas is supplied between the ring assembly 112 and the substrate support 11. A lower side of FIG. 5 indicates a state in which the heat transfer gas is exhausted between the ring assembly 112 and the substrate support 11. In the upper side of FIG. 5, impurities 120 are attached onto the back surface of the ring assembly 120. The pressure of the heat transfer gas is lowered by exhausting the heat transfer gas, and the pressure of the heat transfer gas is lower than that at the time of the plasma processing for the substrate W, and as a result, the impurities 120 flow to the supply path 115b and are removed as indicated in the lower side of FIG. 5. Therefore, the abnormal discharge such as arcing which occurs generated by the impurities 120 may be controlled.

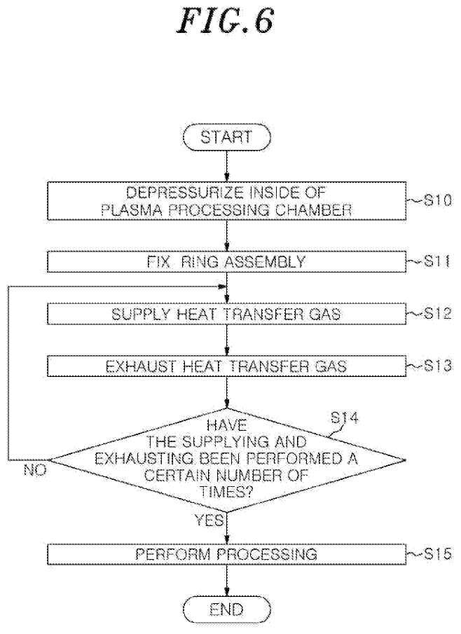

Next, the flow of the processing of the abnormal discharge control method performed by the plasma processing apparatus 1 according to an exemplary embodiment will be described. FIG. 6 is a diagram for describing an example of a processing sequence of an abnormal discharge control method according to an embodiment. In FIG. 6, the processing of the abnormal discharge control method is applied to the control of the abnormal discharge in the ring assembly 112. The ring assembly 112 is mounted on the substrate support 11 when, e.g., the plasma processing apparatus 1 is newly operated, maintenance of the plasma processing apparatus 1 initiates, the ring assembly 112 is exchanged due to consumption, etc. When the ring assembly 112 is mounted on the substrate support 11, the plasma processing apparatus 1 performs seasoning of the ring assembly 112. The processing illustrated in FIG. 6 is executed when the seasoning of the ring assembly 112 is performed.

The controller 2 controls the exhaust system 40 to depressurize the inside of the plasma processing chamber 10 by the exhaust system 40 (S10).

The controller 2 fixes the ring assembly 112 to the substrate support 11 (S11). For example, the controller 2 controls a DC power supply (not illustrated) to apply voltage to the electrostatic chuck 1111 and controls the power supply 30 to apply high-frequency power for adsorption from the power supply 30 to the substrate support 11 to fix the ring assembly 112 to the substrate support 11 by electrostatic adsorption.

The controller 2 controls the gas supply 116 to supply the heat transfer gas between the ring assembly 112 and the substrate support 11 from the gas supply 116 (S12). The controller 2 controls the gas supply 116 to exhaust the heat transfer gas between the ring assembly 112 and the substrate support 11 by the gas supply 116 (S13).

The controller 2 determines whether the supply and the exhaust of the heat transfer gas have been repeatedly performed a certain number of times (S14). The number of times to remove the impurities 120 is determined by experiment or simulation in advance. When the supply and the exhaust of the heat transfer gas have not been performed the certain number of times (No in S14), the process proceeds to the processing of S12.

Meanwhile, when the supply and the exhaust have been performed the certain number of times (Yes in S14), the controller 2 executes the processing of removing the moisture (S15). For example, the controller 2 controls the gas supply 20 to supply the processing gas from the gas supply 20 to introduce the processing gas in the plasma processing chamber 10 from the shower head 13. Further, the controller 2 controls the gas supply 116 to set the pressure of the heat transfer gas supplied between the substrate support 11 and the ring assembly 112 to be lower than that at the time of the plasma processing for the substrate W. Further, the controller 2 controls the power supply 30 to set the power of the RF signal supplied from the power supply 30 to be equal to or lower than that at the time of the plasma processing for the substrate W. For example, the controller 2 controls the power supply 30 so that an RF signal of a power which causes a temperature of the substrate W to be 200° C. or more and is equal to or less than that at the time of the plasma processing for the substrate W is to be supplied from the power supply 30. Further, the controller 2 may perform the processing of S15 in parallel to the processing in S12 and S13. Therefore, in the plasma processing apparatus 1, plasma is generated in the plasma processing chamber 10 and moisture is removed from the ring assembly 112.

Therefore, it is possible to control the occurrence of the abnormal discharge such as arcing between the ring assembly 112 and the substrate support 11.

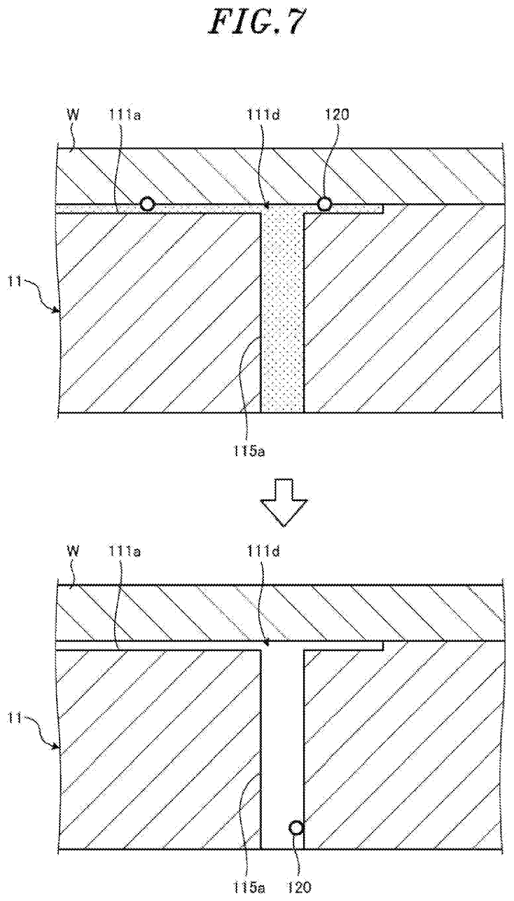

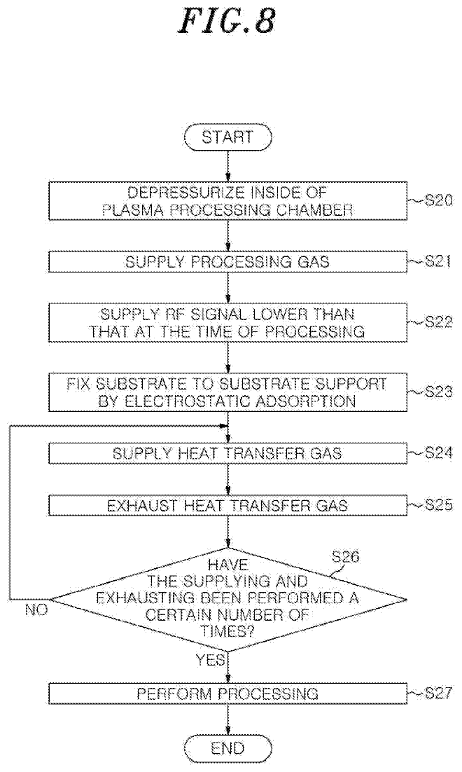

Further, in the exemplary embodiment, the case of performing the processing of the abnormal discharge control method in the seasoning is described as an example. However, the present disclosure is not limited thereto. The processing of the abnormal discharge control method may be also performed when the substrate W is exchanged. For example, there is a case where a defect occurs by impurities 120 attached to a back surface of a substrate W. Therefore, when exchanging the substrate W, the controller 2 may control the gas supply 116 to perform the supply and exhaust of heat transfer gas between the exchanged substrate W and the substrate support 11 at least one time before performing the plasma processing for the substrate W. FIG. 7 is a diagram for describing another example of a flow of removing impurities according to an embodiment. In FIG. 7, a state in the vicinity of the central area 111a of the substrate support 11 is schematically illustrated. An upper side of FIG. 7 indicates a state in which heat transfer gas is supplied between the substrate W and the substrate support 11. A lower side of FIG. 7 indicates a state in which heat transfer gas is exhausted between the substrate W and the substrate support 11. In the upper side of FIG. 7, impurities 120 are attached onto the back surface of the substrate W. The pressure of the heat transfer gas is lowered by exhausting the heat transfer gas, and the pressure of the heat transfer gas is lower than that at the time of the plasma processing for the substrate W, and as a result, the impurities 120 flow to the supply path 115a and are removed as indicated in the lower side of FIG. 7. Therefore, the impurities 120 attached to the back surface of the substrate W may be removed and the abnormal discharge such as arcing which occurs generated by the impurities 120 may be controlled.

FIG. 8 is a diagram for describing another example of a processing sequence of an abnormal discharge control method according to an embodiment. In FIG. 8, the processing of the abnormal discharge control method according to an exemplary embodiment is applied for the control of the abnormal discharge in the substrate W. For example, when plasma processing is performed in the plasma processing apparatus 1, a substrate W is mounted on the substrate support 11. When the substrate W is mounted on the substrate support 11, the plasma processing apparatus 1 executes the processing illustrated in FIG. 8 before performing the plasma processing for the substrate W.

The controller 2 controls the exhaust system 40 to depressurize the inside of the plasma processing chamber 10 by the exhaust system 40 (S20).

The controller 2 controls the gas supply 116 to introduce the processing gas from the gas supply 116 in the plasma processing chamber 10 (S21). For example, the controller 2 controls the gas supply 116 to supply the processing gas from the gas supply 116 to introduce Ar gas in the plasma processing chamber 10.

The controller 2 controls the power supply 30 to supply an RF signal having lower power than that at the time of the plasma processing for the substrate W into the plasma processing chamber 10 from the RF power supply 31 (S22). For example, the controller 2 supplies a RF signal having comparatively low power such as 300 W to the conductive member serving as the lower electrode of the base 1110 from the RF power supply 31 to generate weak plasma and apply the weak plasma on the substrate W.

Further, in the processing of S21, the case of setting the processing as Ar gas and applying the plasma of the Ar gas on the substrate W is described. However, the gas type of processing gas is not limited thereto. The processing gas may be, for example, gas such as O₂ gas, CF₄, N₂ gas, etc. However, the processing gas needs to be a type of gas in which the plasma by the generated gas has little undesired operation such as etching on the substrate W and an inner wall of the plasma processing chamber 10. Further, the processing gas needs to be a type of gas type in which the plasma is easy to ignite. Further, an optimal gas type for the processing gas may change according to which processing has been performed in a previous process for the substrate W for which the plasma processing is to be performed. It is preferable to appropriately select the processing gas by considering these factors.

Here, a reason for applying weak plasma on the substrate W is as follows. The state of the substrate W subjected to the plasma processing may not be uniform depending on the state of the processing in a previous process (e.g., a film forming process such as CVD). For example, there is a case where electric charges are accumulated in the substrate W. When strong plasma is applied to the substrate W in the state in which the electric charges are accumulated in the substrate W, there is a high possibility that surface arcing will occur. Therefore, before applying strong plasma, weak plasma is operated to the substrate W. When weak plasma is applied to the substrate W, the state of the electric charges in the substrate W is adjusted (initialized) uniformly.

As for the substrate W, in the state in which DC voltage (HV) is not applied to the electrostatic chuck 1111, weak plasma is applied thereto. Therefore, the electric charges in the substrate W may be easily moved.

The power of the RF signal for generating weak plasma is approximately 0.15 W/cm² to 1.0 W/cm², e.g., approximately 100-500 W. A time for which weak plasma is applied to the substrate W is, for example, approximately 5 to 20 seconds.

The controller 2 fixes the substrate W to the substrate support 11 by electrostatic adsorption (S23). For example, the controller 2 controls a DC power supply (not illustrated) to apply voltage to the electrostatic chuck 1111 and fix the substrate W to the substrate support 11 by the electrostatic adsorption.

The controller 2 controls the gas supply 116 to supply the heat transfer gas between the substrate W and the substrate support 11 from the gas supply 116. The controller 2 controls the gas supply 116 to exhaust the heat transfer gas between the substrate W and the substrate support 11 by the gas supply 116 (S25).

The controller 2 determines whether the supply and the exhaust of the heat transfer gas have been repeatedly performed a certain number of times (S26). The number of times to remove the impurities 120 is determined by the experiment or the simulation in advance. When the supply and the exhaust of the heat transfer gas have not been performed the certain number of times (No in S26), the process proceeds to the processing of S24.

Meanwhile, when the supply and the exhaust have been performed the certain number of times (Yes in S26), the controller 2 executes the processing of removing the moisture (S27). For example, the controller 2 controls the gas supply 20 to supply the processing gas from the gas supply 20 to introduce the processing gas in the plasma processing chamber 10 from the shower head 13. Further, the controller 2 controls the gas supply 116 to set the pressure of the heat transfer gas supplied between the substrate support 11 and the substrate 11 to be lower than that at the time of the plasma processing for the substrate W. Further, the controller 2 controls the power supply 30 to set the power of the RF signal supplied from the power supply 30 to be equal to or lower than that at the time of the plasma processing for the substrate W. For example, the controller 2 controls the power supply 30 so that an RF signal having a power which causes the temperature of the substrate W to be 200° C. or more, and is equal to or less than that at the time of the plasma processing for the substrate W is to be supplied from the power supply 30. Further, the controller 2 supplies a bias RF signal to the substrate support 11 from the RF power supply 31 during the process of S24, S25, and S27. The controller 2 may perform the processing of S27 in parallel to the processing in S24 and S25. Therefore, in the plasma processing apparatus 1, plasma is generated in the plasma processing chamber 10 and moisture is removed from the substrate W.

Therefore, it is possible to control the occurrence of the abnormal discharge such as arcing between the substrate w and the substrate support 11.

As such, the plasma processing apparatus 1 according to the exemplary embodiment includes the plasma processing chamber 10, the substrate support 11 (mounting stage), the electrostatic chuck 1111 (fixation portion), the gas supply (the heat transfer gas supply and the heat transfer gas exhauster), the power supply 30 (the RF power supply), and the controller 2. In the plasma processing chamber 10, the plasma processing is performed. The substrate support 11 is disposed in the plasma processing chamber 10, and the substrate W and the ring assembly 112 on the periphery of the substrate W are mounted thereon. The electrostatic chuck 1111 is provided in the substrate support 11, and fixes at least one of the substrate W and the ring assembly 112 to the substrate support 11. The gas supply 116 supplies the heat transfer gas between the substrate support 11, and at least one of the substrate W and the ring assembly 112. The gas supply 116 exhausts the heat transfer gas from between the substrate support 11, and at least one of the substrate W and the ring assembly 112. The power supply 30 supplies the RF signal for plasma generation into the plasma processing chamber 10. When at least one of the substrate W and the ring assembly 112 is mounted on the substrate support 11, the controller 2 controls the pressure of the heat transfer gas supplied from the gas supply 116 to be lower than that at the time of the plasma processing for the substrate before performing the plasma processing for the substrate W.

Therefore, the plasma processing apparatus 1 may control the occurrence of the abnormal discharge such as arcing between the substrate W or the ring assembly 112 and the substrate support 11.

The controller 2 executes (a) a process (S12) of supplying the heat transfer gas between the substrate support 11 and the ring assembly 112 and a process (S13) of lowering the pressure of lowering the pressure of the heat transfer gas supplied between the substrate support 11 and the ring assembly 112 than the process of (a). Therefore, the plasma processing apparatus 1 may control the occurrence of the abnormal discharge such as arcing between the ring assembly 112 and the substrate support 11.

Further, the controller 2 controls the gas supply 116 to perform supply and exhaust of the heat transfer gas between the ring assembly 112 and the substrate support 11 at least one time before performing the plasma processing for the substrate W. Therefore, the plasma processing apparatus 1 may remove the impurities 120 attached to the back surface of the ring assembly 112 and control the occurrence of the abnormal discharge such as arcing which generated by the impurities 120.

The controller 2 also controls the power supply 30 so that an RF signal having a power which causes the temperature of the substrate W to be 200° C. or more and is equal to or less than that at the time of the plasma processing for the substrate W is to be supplied from the power supply 30 in processes (a) and (b) (S12 and S13). Therefore, the plasma processing apparatus 1 may remove the moisture attached to the ring assembly 112 quickly.

The controller 2 controls the gas supply 116 so that the pressure of the heat transfer gas supplied between the substrate support 11 and the ring assembly 112 from the gas supply 116 becomes 15 Torr or less in the process of (b) (S13). Therefore, the plasma processing apparatus 1 may also control the occurrence of the abnormal discharge such as arcing between the ring assembly 112 and the substrate support 11 when the RF signal is supplied into the plasma processing chamber 10.

The controller 2 controls the gas supply 116 to alternately perform the supply and the exhaust of the heat transfer gas multiple times. Therefore, the plasma processing apparatus 1 may remove the impurities 120 attached to the substrate W or the back surface of the ring assembly 112. The electrostatic chuck 111 fixes the ring assembly 112 to the substrate support 11 by the electrostatic adsorption. Therefore, the plasma processing apparatus 1 may stably fix the ring assembly 112 to the substrate support 11.

The heat transfer gas is helium gas or hydrogen gas. Therefore, the plasma processing apparatus 1 may stably transfer heat between the substrate support 11, and the substrate W and the ring assembly 112.

When the substrate W is mounted on the substrate support 11, the controller 2 may control the gas supply 116 to perform the supply and exhaust of the heat transfer gas between the substrate W and the substrate support 11 at least one time before performing the plasma processing for the substrate W. Therefore, the plasma processing apparatus 1 may remove the impurities 120 attached to the back surface of the substrate W and control the occurrence of the abnormal discharge such as arcing which generated by the impurities 120.

The electrostatic chuck 111 fixes the substrate W to the substrate support 11 by the electrostatic adsorption. Therefore, the plasma processing apparatus 1 may stably fix the substrate W to the substrate support 11.

The controller 2 executes (a) a process (S21) of introducing the processing gas in the plasma processing chamber 10, (b) a process (S22) of supplying the RF signal having lower power than that at the time of the plasma processing for the substrate W, (c) a process (S23) of electrostatically adsorbing the substrate W to the substrate support 11, (d) processes (S24 and S25) of performing the supply and the exhaust of the heat transfer gas between the substrate W and the substrate support 11 at least one time, and (e) a process (S26) of supplying the processing gas and the RF signal for plasma generation in the plasma processing chamber 10. Therefore, the plasma processing apparatus 1 may control the occurrence of the abnormal discharge such as arcing between the substrate W and the substrate support 11.

The controller 2 executes a process of supplying a bias RF signal (bias signal) to the substrate support 11 from the RF power supply 31 (bias power supply) during the processes of S24, S25, and S27. Therefore, the plasma processing apparatus 1 may generate a bias potential in the substrate W and draw ion components in the formed plasma to the substrate W.

Hereinabove, the exemplary embodiment is described, but it should be considered that the disclosed exemplary embodiment is an example and is not limited in all aspects. Actually, the exemplary embodiment may be implemented in various forms. Further, the exemplary embodiment may be omitted, substituted, and changed without departing from the claims and the spirit.

For example, in the exemplary embodiment, a case of performing plasma processing for a semiconductor wafer as the substrate W is described as an example, but the present disclosure is not limited thereto. The substrate W may be any substrate.

Further, in the exemplary embodiment, the case where the supply and the exhaust of the heat transfer gas are performed in the same path by the supply paths 115a and 115b is described as an example, but the present disclosure is not limited thereto. The path for supplying the heat transfer gas and the path for exhausting the heat transfer gas may be separately provided.

Further, in the exemplary embodiment, the case of fixing the substrate W and the ring assembly 112 to the substrate support 11 by the electrostatic adsorption by the electrostatic chuck 1111 is described as an example, but the present disclosure is not limited thereto. The substrate W and the ring assembly 112 may be fixed to the substrate support 11 by a fixation mechanism such as a hook.

Further, in the exemplary embodiment, the case where the plasma processing apparatus 1 performs plasma etching as the plasma processing is described as an example, but the present disclosure is not limited thereto. The plasma processing apparatus 1 may adopt any apparatus which performs plasma processing for a substrate W. For example, the plasma processing apparatus 1 may be a film forming apparatus that forms a film by generating plasma.

Further, it should be considered that the disclosed exemplary embodiment is an example and is not limited in all aspects. Actually, the exemplary embodiments may be implemented as various forms. Further, the exemplary embodiment may be omitted, substituted, and changed as various forms without departing from the appended claims and the spirit.

Further, the following additional statements are further disclosed regarding the exemplary embodiment.

(Additional Statement 1)

A plasma processing apparatus comprises:

a chamber in which plasma processing is performed;

a mounting stage, disposed in the chamber, mounting a substrate and a ring assembly on a periphery of the substrate;

a fixation portion, provided in the mounting stage, fixing at least one of the substrate and the ring assembly to the mounting stage;

a heat transfer gas supply supplying heat transfer gas between the mounting stage and at least one of the substrate and the ring assembly;

a heat transfer gas exhauster exhausting the heat transfer gas from between the mounting stage and at least one of the substrate and the ring assembly;

an RF power supply supplying a radio frequency (RF) signal for plasma generation into the chamber; and

a controller controlling the heat transfer gas supply so that pressure of the heat transfer gas supplied from the heat transfer gas supply is lower than that at the time of plasma processing for the substrate before performing the plasma processing for the substrate when at least one of the substrate and the ring assembly is mounted on the mounting stage.

(Additional Statement 2)

In the plasma processing apparatus of additional statement 1, the controller executes

(a) a process of supplying the heat transfer gas between the mounting stage and the ring assembly, and

(b) a process of lowering the pressure of the heat transfer gas supplied between the mounting stage and the ring assembly.

(Additional Statement 3)

In the plasma processing apparatus of additional statement 1 or 2, the controller controls the heat transfer gas supply and the heat transfer gas exhauster to perform the supply and the exhaust of the heat transfer gas between the ring assembly and the mounting stage at least one time before performing the plasma processing for the substrate.

(Additional Statement 4)

In the plasma processing apparatus of additional statement 2, the controller controls the RF power supply so that an RF signal having a power which causes a temperature of the substrate to be 200° C. or more and is equal to or less than that at the time of the plasma processing for the substrate is to be supplied from the RF power supply in the processes (a) and (b).

(Additional Statement 5)

In the plasma processing apparatus of additional statement 2, the controller controls the heat transfer gas supply so that the pressure of the heat transfer gas supplied between the mounting stage and the ring assembly from the heat transfer gas supply becomes 15 Torr or less in the process of (b).

(Additional Statement 6)

In the plasma processing apparatus of additional statement 3, the controller controls the heat transfer gas supply to alternately perform the supply and the exhaust of the heat transfer gas multiple times.

(Additional Statement 7)

In the plasma processing apparatus of any one of additional statements 1 to 6, the fixation portion fixes the ring assembly to the mounting stage by electrostatic adsorption.

(Additional Statement 8)

In the plasma processing apparatus of any one of additional statements 1 to 7, the heat transfer gas is helium gas or hydrogen gas.

(Additional Statement 9)

In the plasma processing apparatus of additional statement 1, the controller controls the heat transfer gas supply and the heat transfer gas exhauster to perform the supply and the exhaust of the heat transfer gas between the ring assembly and the mounting stage at least one time before performing the plasma processing for the substrate when the substrate is mounted on the mounting stage.

(Additional Statement 10)

In the plasma processing apparatus of additional statement 9, the controller controls the heat transfer gas supply and the heat transfer gas exhauster to alternately perform the supply and the exhaust of the heat transfer gas multiple times.

(Additional Statement 11)

In the plasma processing apparatus of any one of additional statements 1 to 10, the fixation portion fixes the substrate to the mounting stage by the electrostatic adsorption.

(Additional Statement 12)

In the plasma processing apparatus of additional statement 11, the controller executes

(a) a process of introducing processing gas in the chamber,

(b) a process of supplying an RF signal having a power lower than that at the time of the plasma processing for the substrate into the chamber from the RF power supply,

(c) a process of electrostatically adsorbing the substrate to the mounting stage,

(d) a process of performing the supply and the exhaust of the heat transfer gas between the substrate and the mounting stage at least one time, and

(e) a process of supplying the processing gas and the RF signal for the plasma generation in the chamber.

(Additional Statement 13)

In the plasma processing apparatus of additional statement 12, the apparatus further comprises:

a bias power supply,

wherein the controller executes a process of supplying a bias signal to the mounting stage from the bias power supply between the processes (d) and (e).

(Additional Statement 14)

An abnormal discharge control method comprises:

mounting, on a mounting stage disposed in a chamber in which plasma processing is performed, at least one of a substrate and a ring assembly mounted on a periphery of the substrate; and

lowering pressure of heat transfer gas supplied between the mounting stage and at least one of the substrate and the ring assembly to be lower than that at the time of plasma processing for the substrate before performing the plasma processing for the substrate.

1. A plasma processing apparatus comprising:
a chamber in which plasma processing is performed;
a mounting stage, disposed in the chamber, mounting a substrate and a ring assembly on a periphery of the substrate;
a fixation portion, provided in the mounting stage, fixing at least one of the substrate and the ring assembly to the mounting stage;
a heat transfer gas supply supplying heat transfer gas between the mounting stage and at least one of the substrate and the ring assembly;
a heat transfer gas exhauster exhausting the heat transfer gas from between the mounting stage and at least one of the substrate and the ring assembly;
an RF power supply supplying a radio frequency (RF) signal for plasma generation into the chamber; and
a controller controlling the heat transfer gas supply so that pressure of the heat transfer gas supplied from the heat transfer gas supply is lower than that at the time of plasma processing for the substrate before performing the plasma processing for the substrate when at least one of the substrate and the ring assembly is mounted on the mounting stage.

2. The plasma processing apparatus of claim 1, wherein the controller executes
(a) a process of supplying the heat transfer gas between the mounting stage and the ring assembly, and
(b) a process of lowering the pressure of the heat transfer gas supplied between the mounting stage and the ring assembly.

3. The plasma processing apparatus of claim 2, wherein the controller controls the heat transfer gas supply and the heat transfer gas exhauster to perform the supply and the exhaust of the heat transfer gas between the ring assembly and the mounting stage at least one time before performing the plasma processing for the substrate.

4. The plasma processing apparatus of claim 2, wherein the controller controls the RF power supply so that an RF signal having a power which causes a temperature of the substrate to be 200° C. or more and is equal to or less than that at the time of the plasma processing for the substrate is to be supplied from the RF power supply in the processes (a) and (b).

5. The plasma processing apparatus of claim 2, wherein the controller controls the heat transfer gas supply so that the pressure of the heat transfer gas supplied between the mounting stage and the ring assembly from the heat transfer gas supply becomes 15 Torr or less in the process of (b).

6. The plasma processing apparatus of claim 3, wherein the controller controls the heat transfer gas supply to alternately perform the supply and the exhaust of the heat transfer gas multiple times.

7. The plasma processing apparatus of claim 2, wherein the fixation portion fixes the ring assembly to the mounting stage by electrostatic adsorption.

8. The plasma processing apparatus of claim 1, wherein the heat transfer gas is helium gas or hydrogen gas.

9. The plasma processing apparatus of claim 1, wherein the controller controls the heat transfer gas supply and the heat transfer gas exhauster to perform the supply and the exhaust of the heat transfer gas between the ring assembly and the mounting stage at least one time before performing the plasma processing for the substrate when the substrate is mounted on the mounting stage.

10. The plasma processing apparatus of claim 9, wherein the controller controls the heat transfer gas supply and the heat transfer gas exhauster to alternately perform the supply and the exhaust of the heat transfer gas multiple times.

11. The plasma processing apparatus of claim 9, wherein the fixation portion fixes the substrate to the mounting stage by the electrostatic adsorption.

12. The plasma processing apparatus of claim 11, wherein the controller executes
(a) a process of introducing processing gas in the chamber,
(b) a process of supplying an RF signal having a power lower than that at the time of the plasma processing for the substrate into the chamber from the RF power supply,
(c) a process of electrostatically adsorbing the substrate to the mounting stage,
(d) a process of performing the supply and the exhaust of the heat transfer gas between the substrate and the mounting stage at least one time, and
(e) a process of supplying the processing gas and the RF signal for the plasma generation in the chamber.

13. The plasma processing apparatus of claim 12, further comprising:
a bias power supply,
wherein the controller executes a process of supplying a bias signal to the mounting stage from the bias power supply between the processes (d) and (e).

14. An abnormal discharge control method comprising:
mounting, on a mounting stage disposed in a chamber in which plasma processing is performed, at least one of a substrate and a ring assembly mounted on a periphery of the substrate; and
lowering pressure of heat transfer gas supplied between the mounting stage and at least one of the substrate and the ring assembly to be lower than that at the time of plasma processing for the substrate before performing the plasma processing for the substrate.
